(19) United States
(12) Patent Application Publication
(10) Pub. No.: US 2015/0211126 A1
(43) Pub. Date: Jul. 30, 2015

(54) DIRECT LIQUID INJECTION OF SOLUTION BASED PRECURSORS FOR ATOMIC LAYER DEPOSITION

(71) Applicants: Ce MA, (US); LINDE AKTIENGESELLSCHAFT, Munich (DE)

(72) Inventor: Ce Ma, Oceanside, CA (US)

(21) Appl. No.: 14/426,507

(22) PCT Filed: Sep. 5, 2013
(86) PCT No.: PCT/US13/58122

§ 371 Date: Mar. 6, 2015

Related U.S. Application Data
(60) Provisional application No. 61/697,940, filed on Sep. 7, 2012.

(51) Int. Cl. C23C 16/52; C23C 16/448; C23C 16/455

(52) U.S. Cl. CPC C23C 16/52; C23C 16/45544; C23C 16/45557; C23C 16/4482

(57) ABSTRACT

Systems and methods for the precise control of the delivery of solution-based precursors for use in ALD processes. By using direct liquid injection of the precursor solution to a local vaporizer, the vaporization of the solution-based precursors and delivery of the vaporized precursor can be precisely controlled in order to achieve true ALD film growth with a conversional ALD tool.

### FIELD OF THE INVENTION

The present invention relates to methods and systems for delivering and vaporizing solution based precursors for use in atomic layer deposition processes.

### BACKGROUND OF THE INVENTION

Moore's law predicts the long-term trend whereby the doubling of the number of transistor that can he inexpensively on an integrated circuit occurs approximately every two years. The capabilities of digital electronic devices, e.g. processing speed, memory capacity, etc. have been strongly linked to Moore's for the last half century and is expected to continue for several more years.

However, as semiconductor devices continue to get more densely packed with devices in accordance with Moore's law, channel lengths have to he made smaller and smaller and chip performance will have to he enhanced while reducing unit costs. To meet these needs, new materials for use in conjunction with silicon-based IC chips will need to be developed and used. For example, the use of transition metals and lanthanide metals has been suggested for USC in critical functionalities of electronic devices. Oxides of these metals may he used to replace the current SiO₂ and SiON gate dielectrics as they can he deposited as ultra thin, effective oxide thickness less than 1.5 nm, high-k oxides. Examples of high-k materials that have acceptable properties, such as high band gaps and band offsets, good stability on silicon, minimal SiO₂ interface layers, and high quality interfaces on substrates, are described in published U.S. patent application 20100055321 and issued U.S. Pat. No. 7,514,119, each incorporated herein by reference. More specific examples of precursors that are useful for depositing such high-k materials are described in published U.S. patent application 20090305504, published U.S. patent application 20090117274, published U.S. patent application 20100290945, published U.S. patent application 20100290963 and published PCT patent application 2011005653, each incorporated herein by reference.

Atomic layer deposition (ALD) is the enabling deposition technology for the next generation conductor barrier layers; high-k gate dielectric layers for silicon, germanium and carbon based group IV elemental semiconductors; high-k gate dielectric layers for InGaAs and other III-V high electron mobility semiconductors; high-k gate dielectric layers for carbon based electronics, such as carbon nanotube and graphene applications; high-k capacitor layers for DRAM; high-k dielectric layers for flash and ferroelectric memory devices; Magnetic junction layers for STT-MRAM, function layers in phase-change memory and resistive RAM memory; metal-based catalyst layers for gas purification, organic synthesis, fuel cell membranes and chemical detectors; metal-based surfaces for electrode materials in fuel cells; capping layers; metallic gate electrodes, etc. However, many of the precursors noted in the references above can he difficult to use in vapor phase deposition processes such as ALD, because these precursors have generally low volatility and exist as solids at room temperatures. Therefore as noted in the above references the precursor materials must be combined with suitable solvents to create solution-based precursors prior to use in the deposition process. ALD processing is the most beneficial technology for deposition of such solution-based precursors because ALD is used to build ultra thin and highly conformal layers of metal, oxide, nitride, and others one monolayer at a time in a cyclic deposition process. ALD processes can be also used in the manufacturing of flat panel displays, compound semiconductors, magnetic and optical storage devices, solar cells, nanotechnology and nanomaterials.

A typical ALD process uses sequential precursor gas pulses to deposit a film one layer at a time. In particular, a first precursor gas is introduced into a process chamber and produces a monolayer by reaction at the surface of a substrate in the chamber. A second precursor is then introduced to react with the first precursor and form a monolayer of film made up of components of both the first precursor and second precursor, on the substrate. Each pair of pulses (one cycle) produces exactly one monolayer of film allowing for very accurate control of the final film thickness based on the number of deposition cycles performed.

As set out in the references noted above, for ALD processes, the precursors should have good volatility and be able to saturate the substrate surface quickly through chemisorptions and surface reactions. The ALD half reaction cycles should be completed within 5 seconds, preferably within 1 second and exposure dosage should be below 10⁸ Langmuir (1 Torr*sec=10⁶ Langmuir). The precursors themselves should also be highly reactive so that the surface reactions are fast and complete, as complete reactions yield good purity in the films produced. Because of the important controls needed for the deposition parameters of these solution-haled precursors, the delivery and vaporization mechanism is important. The equipment and techniques used must be capable of maintaining stability of the solution-based precursor material within the deposition temperature window in order to avoid uncontrolled CVD reactions from occurring.

In general, the standard commercial delivery and vaporizer systems are not suitable for solution-based precursors. This is in part because it is difficult to deliver a small enough dose of precursor needed to limit monolayer coverage of the substrate. In particular, the pulse width of the vapor phase reactant is 1 second or less and the shape of the vaporized liquid pulse may be distorted with sharp leading and tailing edges of the liquid pulse being lost after vaporization. It is very difficult to synchronize two well separated reactants to perform the desired self-limiting and sequential ALD growth.

For example, the Savannah™ Series ALD system from Cambridge NonoTech, is representative of available ALD systems. This system provides means to deposit ALD films on 200 mm wafer surfaces using static one-end source containers. Neat precursor vapor that has higher pressure than chamber operating pressure is delivered by ALD pulse valves from Swagelok. To obtain high enough precursor vapor pressure, the one-end source containers may be heated by electrical heating jackets with temperature controls. However, the use of solution-based precursors in the standard Savannah ALD tool is difficult, because solvent and solute in the solution-based precursors are separated in the vapor phase during pulse at the control temperature. Higher volatile components, generally the solvents, are therefore enriched on the head space of the source container, causing deposition inconsistencies.

Direct liquid injection methods can be used to control the vaporization and pulse of precursor materials. U.S. published patent application 2003/0056728 discloses a pulsed liquid injection method in an atomic vapor deposition (AVD) process using a precursor in liquid or dissolved form. However, the liquid dose is too large to meet ALD growth requirements. Min, et al., “Atomic layer deposition of Al₂O₃ thin films from a 1-methoxy-2-methyl-2-propoxide complex of aluminum and water”, Chemistry Materials (2005), describes a liquid pulsing method for solution precursors, where the liquid dose is again too large for ALD growth to occur, Neither of these liquid pulse methods provide ALD growth, but instead represent variants of CVD processes and result in uncontrolled CVD layer growth.

Methods and apparatus related to the vaporization and delivery of solution-based precursors in ALD processes are described in published U.S. patent application 20100036144 and published U.S. patent application 20100151261, both incorporated herein by reference.

There remains a need in the art for improvements to the delivery and vaporization of ALD solution-based precursors. In particular, the ability to use local vaporizers that fit into existing commercial ALD wafer tools is needed.

### SUMMARY OF INVENTION

The present invention provides methods and systems for the delivery of solution-based precursors to local vaporizers that are integral with standard ALD wafer tools, More particularly, the present invention provides method and systems wherein the delivery and vaporization of solution-based precursors is precisely controlled by liquid pulses of the precursors into the local vaporizers, full vaporization of the liquid pulsed into the local vaporizer, vapor phase ALD pulses of the fully vaporized precursor into the deposition chamber, and similar pulsing of cleaning inert gas pulses into the chamber. This process achieves true controlled ALD film growth. The liquid pulse can be either solution-based precursor or cleaning solvent from a dual source Flex-ALD container without any dead volumes.

### BRIEF DESCRIPTION OF THE DRAWINGS

FIG. 1 is a schematic diagram of an ALD deposition system according to one embodiment of the invention.

FIG. 2 is a schematic diagram of an ALD deposition system according to another embodiment of the invention.

FIGS. 3A, 3B and 3C are time diagrams showing pulse sequences for operation of the system of the invention.

### DETAILED DESCRIPTION OF THE INVENTION

The present invention provides methods and systems for the precise control of the delivery of solution-based precursors for use in ALD processes. By using direct liquid injection of the precursor solution to a local vaporizer, the vaporization of the solution-based precursors and delivery of the vaporized precursor can be precisely controlled in order to achieve true ALD film growth.

The system of the present invention provides a means of introducing solution-based liquid precursors by direct liquid injection to a local vaporizer on a standard ALD wafer tool. The solution-based precursor is transported by liquid mass flow control at room temperature so that the precursor material has a low thermal budget and to prevent any thermal degradation of the precursor. The solution-based precursor is then vaporized inside the local vaporizer to provide a gas phase precursor and solvent vapor for the ALD operation. The system according to the present invention can he a drop-in replacement of a standard static heated source container and requires no modification of the deposition chamber or precursor manifold.

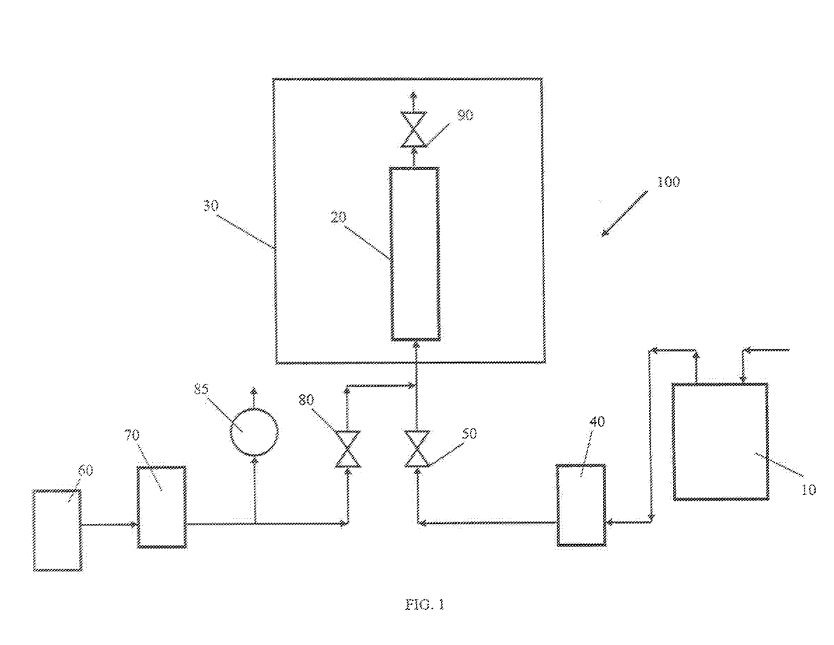

The system of the present invention be described in greater detail with reference to the drawing figures. In particular, FIG. 1 is a schematic diagram of a solution-based precursor delivery system with a local vaporizer 100, comprising solution based precursor source container 10 in communication with a local vaporizer 20 housed within a standard ALD wafer tool precursor manifold 30. The communication between the container 10 and vaporizer 20 passes through a liquid mass flow controller 40 and a liquid pulse valve 50. An inert gas source 60 also communicates with the vaporizer 20 through a gas mass flow controller 70 and gas pulse valve 80 and can be regulated using a back pressure regulator 85. The system 100 also includes a vapor pulse valve 90 connected to the outlet of the vaporizer 20.

The solution-based precursor delivery system 100 operates according to the following process. Solution-based precursor material is prepared, such as the precursor materials described in the several published patent applications and issued patents noted in the background section of this application. The prepared solution based precursor is filled into an inner vessel of container 10, that can be a dual ALD bubbler container, such as that described in published U.S. patent application 2010/0140120, incorporated herein by reference. Pure solvent, such as octane is filled into the outer vessel of the container 10. Using such a container 10 allows for delivery of ether pure solvent or precursor solution to be switched for delivery to the vaporizer 20 without line break. The solvent or precursor solution delivered to the vaporizer is carefully controlled using the liquid mass flow controller 40 and liquid pulse valve 50. The mass flow controller 40 is preferably a low delta T liquid mass flow controller, wherein the temperature increase or decrease of delivered material is less than 5° C. and preferably less than 3° C. This control avoids the formation of bubbles and also avoids component separation of the delivered material as well as reducing bubble formation in the liquid delivery lines. The liquid pulse valve 50 delivers a precisely controlled amount of liquid at room temperature into the vaporizer 20. The vaporizer 20 may be constructed of stainless steel and may include VCR connections as well as a built-in liquid injection nozzle. The liquid precursor solution delivered to the vaporizer 20 is then fully vaporized without phase separation by the vaporizer 20 at temperatures up to 250° C., preferably at temperatures from 100° C. to 200° C. If it is desired to pressurize the vaporized precursor, inert gas from inert gas from inert gas source 60 can be delivered to the vaporizer 20 along with the precursor solution. The inert gas is delivered in a controlled amount through gas mass flow controller 70 and gas pulse valve 80 and hack pressure is regulated by regulator 85. Once the precursor material has been vaporized, the precursor material is delivered in a precisely controlled manner to the wafer deposition chamber 30 through vapor pulse valve 90. This precise control allows the precursor vapor to be delivered without leading and trailing edge formation. Following deposition, the wafer chamber can be purged with inert gas.

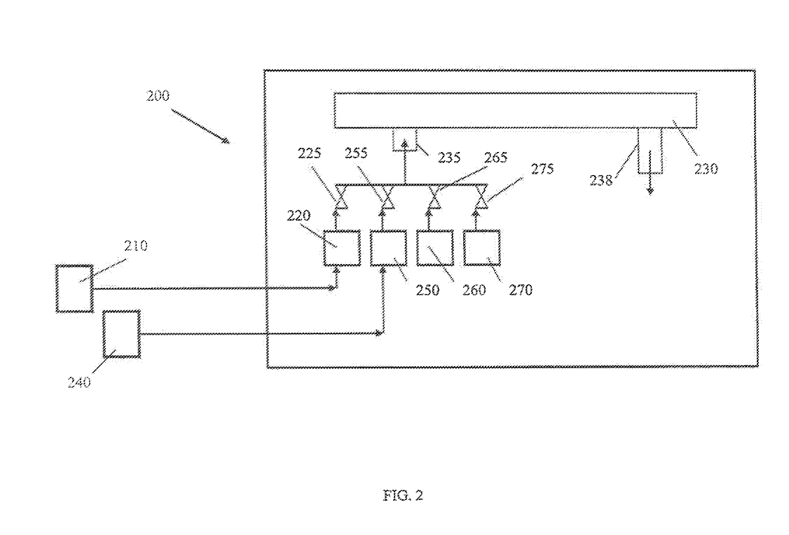

FIG. 2 is a schematic diagram of an ALD deposition system 200 with solution-based precursor delivery systems such as those shown in FIG. 1 according to the invention. In ALD system 200, more than one precursor source container can be employed. In particular, a first solution-based precursor delivery system 210 communicates with a first local vaporizer 220 and first vapor pulse valve 225 for delivery of precursor material to a deposition chamber 230 through inlet 235. A second solution-based precursor delivery system 240 communicates with a second local vaporizer 250 and second vapor pulse valve 255 for delivery of another precursor material to a deposition chamber 230 through inlet 235. In addition other reactants, such as DI water or neat liquid precursors can be stored in standard one-ended source containers, such as containers 260 and 270 for delivery of such reactants to the deposition chamber 230 through respective valves 265 and 275 communicating with chamber inlet 235. Unreacted treatment materials exit the chamber 230 through exhaust port 238. The system 200 provides all of the benefits of the present invention in addition to greater versatility in deposition operation, with greater choice of precursor and other reactant materials.

One operation sequence for the ALD system 200 comprises delivering the first precursor material to the first local vaporizer 220 to be vaporized and then delivered as a precisely controlled pulse to the deposition chamber 230 through the first vapor pulse valve 225. In order to complete the ALD cycle, the second precursor material is then delivered to the second local vaporizer 250 to be vaporized and then delivered as a precisely controlled pulse to the deposition chamber 230 through the second vapor pulse valve 255. Purge steps may be added before, between and after the two precursor deliveries. In one alternative, instead of a second solution based precursor being used, a neat liquid precursor can be substituted and delivered for example from a container 260 or 270. A further embodiment provides for the addition of a third solution based precursor material to be delivered to through a third vaporizer to the deposition chamber. Alternatively, a third precursor material could be a neat liquid precursor delivered from a standard container.

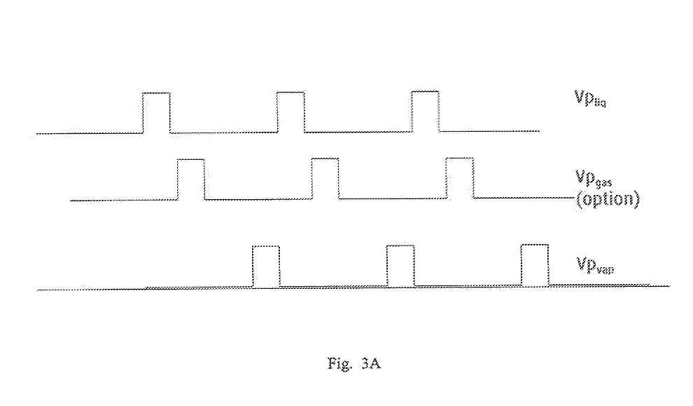

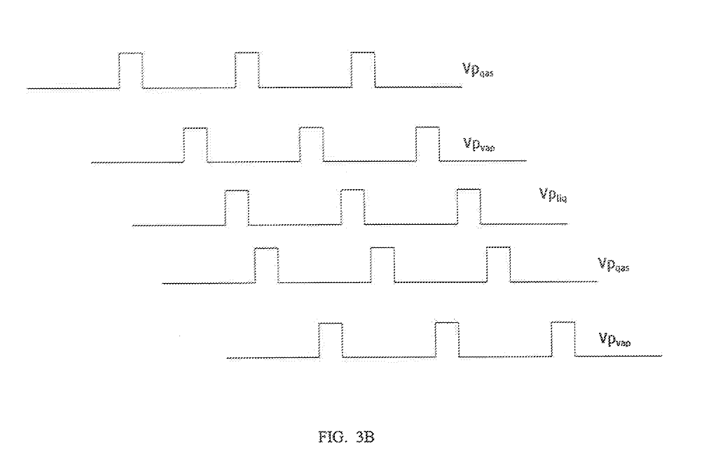

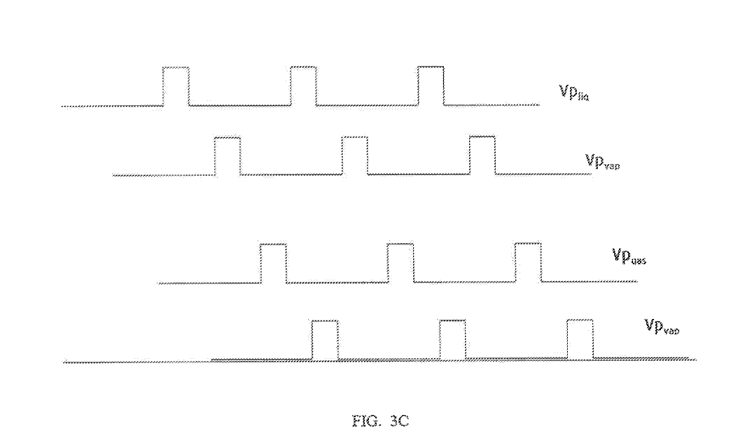

FIGS. 3A, 3B and 3C are time diagrams showing puke sequences for operation of the system of the invention. In particular, FIG. 3A is a time diagram of the operation of the valves 50, 80 and 90 of the system 100 shown in FIG. 1. As shown, liquid puke valve 50 is opened to pulse liquid precursor to the vaporizer. Optionally, gas pulse valve 80 is then opened to pulse inert gas to the vaporizer to pressurize the precursor vapor. Following vaporization, vapor pulse valve 90 is opened to deliver vaporized precursor material to the deposition chamber, The valve operation sequence is then repeated until the desired film deposition thickness is achieved.

FIG. 3B is a time diagram of the operation of the valves 50, 80 and 90 of the system 100 shown in FIG. 1 and includes vaporizer pre-cleaning. As shown, gas pulse valve 80 is opened to send purge ins to the vaporizer. Liquid pulse valve 50 is then opened to pulse liquid precursor to the vaporizer. Optionally, gas pulse valve 80 is again opened to pulse inert gas to the vaporizer to pressurize the vaporized precursor. Following vaporization, vapor pulse valve 90 is opened to deliver vaporized precursor material to the deposition chamber. The valve operation sequence is then repeated until the desired film deposition thickness is achieved.

FIG. 3C is a time diagram of the operation of the valves 50, 80 and 90 of the system 100 shown in FIG. 1 and includes post cleaning. As shown, liquid pulse valve 50 is opened to pulse liquid precursor to the vaporizer. Following vaporization, vapor pulse valve 90 is opened to deliver vaporized precursor material to the deposition chamber. The gas pulse valve 80 is then opened to send purge gas to the vaporizer and the vapor pulse valve 90 is again opened to send the purge gas to the deposition chamber for cleaning. The valve operation sequence is then repeated until the desired film deposition thickness is achieved.

The invention provides for very precise control of the ALD deposition process. Table 1 sets forth two examples of films obtained using the system of the invention.

TABLE 1

| | | | Average | |
|---|---|---|---|---|
| Solute | Solvent | Concentration | Thickness | Growth Rate |
| (tBuCp)₂HfMe₂ | n-Octane | 0.1M | 56.8 Å | 0.28 Å/cycle |
| (tBuCp)₂HfMe₂ | n-Octane | 0.1M | 142 Å | 0.28 Å/cycle |

It is anticipated that other embodiments and variations of the present invention will become readily apparent to the skilled artisan in the light of the foregoing description, and it is intended that such embodiments and variations likewise be included within the scope of the invention as set out in the appended claims. For example, many different piping and valve arrangements can be utilized without departing from the invention. Further, virtually any arrangement of the container and chambers within the container is possible. For example, a cylinder within cylinder arrangement that requires only a single inert gas feed for pressurization of the head space for both chambers is possible.

What is claimed:

1. A system for atomic layer deposition comprising:
an ALD deposition chamber;
a precursor manifold communicating with the deposition chamber and housing a vaporizer having a vapor pulse valve;
a solution based precursor source container communicating with the vaporizer through a liquid mass flow controller and a liquid pulse valve; and
an inert gas source container communicating with the vaporizer through a gas mass flow controller and a gas pulse valve.

2. The system of claim 1 wherein the solution based precursor source container is a dual ALD bubbler container.

3. The system of claim 1 wherein the liquid mass flow controller is a low delta T liquid mass flow controller.

4. The system of claim 1 wherein the temperature increase or decrease through the liquid mass flow controller is less than 5° C.

5. The system of claim 1 wherein the temperature increase or decrease through the liquid mass flow controller is less than 3° C.

6. The system of claim 1 wherein the vaporizer operates at temperatures up to 250° C.,

7. The system of claim 1 wherein the vaporizer operates at temperatures between 100° C. and 200° C.

8. The system of claim 1 further comprising a hack pressure regulator associated with the communication between the inert gas source container and the vaporizer.

9. The system of claim 1 further comprising a second solution based precursor source container communicating with a second vaporizer through a second liquid mass flow controller and a second liquid pulse valve.

10. The system of claim 1 further comprising at least one reactant source container communicating with the deposition chamber through a valve.

11. A method of atomic layer deposition comprising:
delivering a precisely controlled pulse of a first solution based precursor from a first precursor source container to a first vaporizer through a first liquid mass flow controller and a first liquid pulse valve;
vaporizing the precursor in the vaporizer;
delivering the vaporized precursor pulse to an ALD deposition chamber through a vapor ALD valve, the pulse having a square wave like precursor vapor dosage with well rounded leading and trailing edges;
delivering purge gas through at least the deposition chamber;
delivering a second precursor to the ALD deposition chamber through a vapor ALD valve, the pulse having a square wave like precursor vapor dosage with well rounded leading and trading edges;
delivering purge gas through at least the deposition chamber; and
repeating the above steps until the desired film thickness is deposited on a substrate in the deposition chamber.

12. The method of claim 11 wherein vaporization is carried out at temperatures up to 250° C.

13. The method of claim 11 wherein the vaporization is carried out at temperatures between 100° C. and 200° C., the temperature chosen to correspond with the formulation of the solution based precursor being vaporized.

14. The method of claim 11 further comprising after delivering a precisely controlled amount of inert gas from an inert gas source to the vaporizer in addition to the solution based precursor, the inert gas being delivered through a gas mass flow controller and a gas pulse valve, the inert gas assisting the delivery of the vaporized precursor pulse.

15. The method of claim 11 wherein delivering a second precursor comprises delivering a reactant gas to the deposition chamber.

16. The method of claim 11 wherein delivering a second precursor comprises;
delivering a precisely controlled pulse of a second solution based precursor from a second precursor source container to a second vaporizer through a second liquid mass flow controller and a second liquid pulse valve;
vaporizing the second precursor in the second vaporizer; and
delivering the second vaporized precursor pulse to the ALD deposition chamber through a second vapor ALD valve, the second pulse having a square wave like precursor vapor dosage with well rounded leading and trailing edges.

17. The method of claim 11 further comprising delivering a third precursor to the ALD deposition chamber.

18. The method of claim 17 wherein delivering a third second precursor comprises delivering a reactant gas to the deposition chamber.

19. The method of claim 17 wherein delivering a third precursor comprises:
delivering a precisely controlled pulse of a third solution based precursor from a third precursor source container to a third vaporizer through a third liquid mass flow controller and a third liquid pulse valve;
vaporizing the third precursor in the third vaporizer; and
delivering the third vaporized precursor pulse to the ALD deposition chamber through a third vapor ALD valve, the third pulse having a square wave like precursor vapor dosage with well rounded leading and trailing edges,

20. The method of claim 11 further comprising prior to delivering the first solution based precursor, delivering a purge gas through the first vaporizer and the deposition chamber.
